(19) United States
(12) Patent Application Publication
(10) Pub. No.: US 2026/0160617 A1
(43) Pub. Date: Jun. 11, 2026

(54) ARTIFICIAL NOCICEPTOR

(71) Applicant: SK hynix Inc., Icheon-si (KR)

(72) Inventors: Jae Hyuk PARK, Icheon-si (KR); Ji Hun KIM, Icheon-si (KR); Sang Min LEE, Icheon-si (KR)

(21) Appl. No.: 19/182,337

(22) Filed: Apr. 17, 2025

(30) Foreign Application Priority Data
Aug. 23, 2024 (KR) 10-2024-0113788

(51) Int. Cl. G01L 1/16; G01R 19/14; G01R 19/165

(52) U.S. Cl. CPC G01L 1/16; G01R 19/14; G01R 19/16533

(57) ABSTRACT

An artificial nociceptor may include a sensor configured to convert a damaging force into electric energy, a conversion circuit configured to generate an input voltage having a form of a cycle signal having a frequency and amplitude changed, based on the electric energy, and a storage circuit including a plurality of memory cells and configured to provide the input voltage to first memory cells included in a selected area, among the plurality of memory cells.

### CROSS-REFERENCE TO RELATED APPLICATION

This application claims priority under 35 U.S.C. § 119(a) to Korean Patent Application No. 10-2024-0113788, filed in the Korean Intellectual Property Office on Aug. 23, 2024, the entire contents of which are incorporated herein by reference.

### BACKGROUND

### 1. Technical Field

Embodiments relate to integrated circuit technology, specifically to an artificial nociceptor.

### 2. Related Art

Recently, as an electronic device is reduced in size, has lower power consumption and higher performance, and is diversified, memory capable of storing information is required for various electronic devices, such as computers and portable communication devices.

Furthermore, research on memory continues in the neuromorphic field in which electronic circuits and systems that mimic the structure and function of the human brain are being developed.

### SUMMARY

In an embodiment, an artificial nociceptor may include a sensor configured to convert a damaging force into electric energy, a conversion circuit configured to generate an input voltage having a form of a cycle signal having a frequency and amplitude changed, based on the electric energy, and a storage circuit including a plurality of memory cells and configured to provide the input voltage to first memory cells included in a selected area, among the plurality of memory cells.

In an embodiment, an operating method of an artificial nociceptor may include switching the state of memory cells of a storage circuit to a reset state, detecting a damaging force through a sensor, generating an input voltage corresponding to the damaging force, providing the input voltage to memory cells included in a selected area, among the memory cells of the storage circuit, and determining the intensity of stress for the damaging force based on the amount of a current that flows through the memory cells of the selected area.

### BRIEF DESCRIPTION OF THE DRAWINGS

FIG. 1 illustrates an artificial nociceptor according to an embodiment of the present disclosure.

FIG. 2 describes an operation of a sensor in the artificial nociceptor according to an embodiment of the present disclosure.

FIGS. 3A and 3B describe an operation of a conversion circuit in the artificial nociceptor according to an embodiment of the present disclosure.

FIGS. 4, 5, 6A, and 6B describe characteristics of memory that is used in the artificial nociceptor according to an embodiment of the present disclosure.

FIGS. 7 to 9 illustrate an operation of the artificial nociceptor according to an embodiment of the present disclosure.

### DETAILED DESCRIPTION

Hereinafter, embodiments according to the technical spirit of the present disclosure are described with reference to the accompanying drawings.

Embodiments of the present disclosure provide an artificial nociceptor within the neuromorphic field.

Integration within the neuromorphic field can be effectively achieved by implementing memory in the artificial nociceptor.

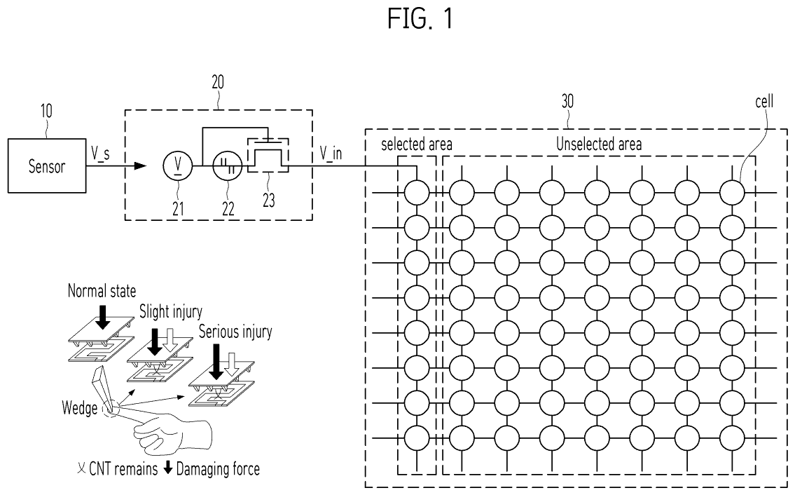

FIG. 1 illustrates an artificial nociceptor according to an embodiment of the present disclosure.

Referring to FIG. 1, the artificial nociceptor may include a sensor 10, a conversion circuit 20, and a storage circuit 30.

The sensor 10 may adjust the level of a sensing voltage V_s based on the intensity of a damaging force applied to an object such as a human's finger. For example, as the intensity of the damaging force increases, the sensor 10 may output the sensing voltage V_s with a higher level. In an embodiment, the sensor 10 may be implemented using a piezoelectric element, which can convert a mechanical change, such as pressure, force, or acceleration, into an electric signal having electric energy.

The conversion circuit 20 may generate an input voltage V_in based on the level of the sensing voltage V_s. The conversion circuit 20 may provide the storage circuit 30 with the input voltage V_in. In this case, the input voltage V_in may be in the form of a cycle signal. A frequency and amplitude of the input voltage V_in may vary based on the level of the sensing voltage V_s.

For example, the conversion circuit 20 may generate the input voltage V_in with a higher frequency as the level of the sensing voltage V_s increases. Furthermore, the conversion circuit 20 may generate the input voltage V_in with greater amplitude as the level of the sensing voltage V_s increases.

In an embodiment, the conversion circuit 20 may include a voltage circuit 21, a memory cell or switching cell 22, and a transistor 23. The voltage circuit 21 may generate a voltage that varies based on the level of the sensing voltage V_s. This voltage may be supplied to one end of the memory or switching cell 22 and to a gate of the transistor 23, both of which receive the voltage generated based on the level of the sensing voltage V_s.

The memory cell or switching cell 22 may have the one end connected to the voltage circuit 21 and the other end connected to a drain of the transistor 23. A node at which the voltage circuit 21 and the one end of the memory cell or switching cell 22 are connected may be connected to the gate of the transistor 23. The input voltage V_in may be output from a source of the transistor 23. The memory cell or switching cell 22 may be turned on and off repeatedly based on the voltage level at the one end of the memory cell or switching cell 22. In this case, the high-frequency input voltage V_in may be generated because the memory cell or switching cell 22 may achieve shorter turn-on and turn-off periods as the voltage level at the one end of the memory cell or switching cell 22 increases.

Furthermore, the degree that the memory cell or switching cell 22 is turned on may increase as the output of the voltage circuit 21 reaches a high voltage level, because the output of the voltage circuit 21 is provided to the gate of the transistor 23. The transistor 23 may output the input voltage V_in with greater amplitude as the degree that the memory cell or switching cell 22 is turned on increases. Hereinafter, the cell labeled 22 in FIG. 1 will be referred to as the memory cell 22.

The storage circuit 30 may include a plurality of memory cells, whose threshold voltages are changed based on the input voltage V_in. The storage circuit 30 may be designed such that the threshold voltages of memory cells included in a selected area, among the plurality of memory cells, are changed based on the input voltage V_in. In this case, the selected area of the storage circuit 30 may include memory cells that receive the input voltage V_in generated by the specific sensor 10.

The memory cell included in the artificial nociceptor may exhibit characteristics of a switching element whose threshold voltage is changed based on the direction of a current that flows through the switching element. The memory cell may utilize a chalcogenide-series ovonic threshold switch (OTS) material.

The artificial nociceptor has been described as including one sensor 10, one conversion circuit 20, and one storage circuit 30. However, it should be noted that the numbers of sensors, conversion circuits, and storage circuits are not limited. Furthermore, if multiple sensors are employed, there may also be multiple conversion circuits. Additionally, the storage circuit 30 may include a plurality of selected areas corresponding to each sensor.

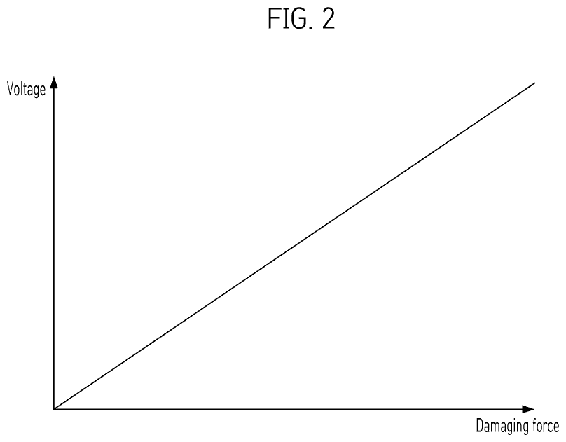

FIG. 2 describes an operation of the sensor 10 in the artificial nociceptor according to an embodiment of the present disclosure.

Referring to FIG. 2, the sensor 10 may generate a higher sensing voltage V_s as a damaging force increases. If the sensor 10 includes a piezoelectric element, the level of the sensing voltage V_s may vary based on the magnitude of pressure applied to the sensor 10. For example, the sensor 10 may generate the higher sensing voltage V_s as the applied pressure increases.

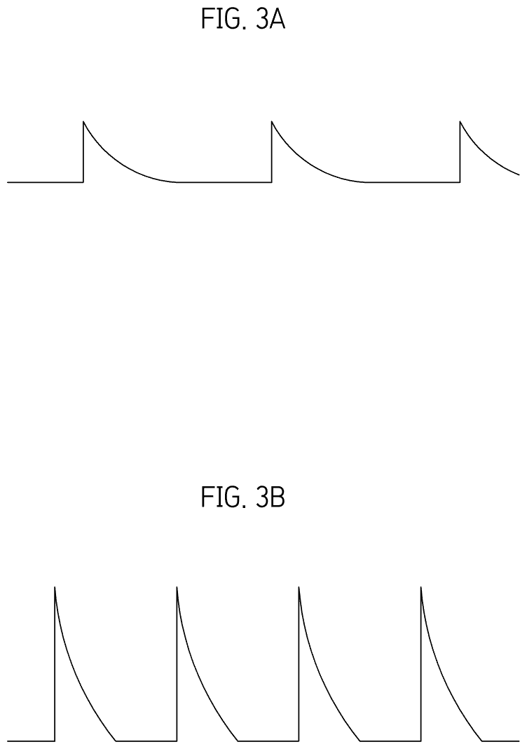

FIGS. 3A and 3B describe an operation of the conversion circuit 20 in the artificial nociceptor according to an embodiment of the present disclosure. In this case, FIGS. 3A and 3B illustrate the input voltage V_in that varies based on the level of the sensing voltage V_s.

The conversion circuit 20 may generate the input voltage V_in in the form of a cycle signal, with its frequency and amplitude varying based on the level of the sensing voltage V_s provided by the sensor 10. As the level of the sensing voltage V_s increases, the conversion circuit 20 may generate the input voltage V_in that has greater amplitude and a higher frequency.

FIG. 3A may present a graph of the input voltage V_in corresponding to the sensing voltage V_s that is lower than that shown in FIG. 3B.

As illustrated in FIG. 1, the conversion circuit 20 may include the voltage circuit 21, the memory cell 22, and the transistor 23. The voltage circuit 21 may provide a higher voltage to the memory cell 22 as the level of the sensing voltage V_s increases. The memory cell 22 may have one end receiving a voltage provided by the voltage circuit 21, while the other end is connected to the transistor 23. When the voltage provided by the voltage circuit 21, that is, electric energy, accumulates at the one end of the memory cell 22 and exceeds the threshold voltage of the memory cell 22, the memory cell 22 may be turned on. Once the memory cell 22 is turned on, it may transfer the electric energy from the one end to the other end. In other words, the memory cell 22, after being turned on, may transmit the accumulated electric energy from the voltage circuit 21 to the transistor 23. After transmitting the accumulated electric energy to the transistor 23, the memory cell 22 may be turned off.

Furthermore, the gate of the transistor 23 may be connected to the node where the memory cell 22 and the voltage circuit 21 are connected. Accordingly, the degree to which the transistor 23 is turned on may vary based on the level of the voltage provided by the voltage circuit 21. For example, the transistor 23 may be turned on to a greater extent as the voltage at its gate increases. As the degree of activation of the transistor 23 increases, it may transmit a greater amount of electric energy to the storage circuit 30 as the input voltage V_in.

Accordingly, as the level of the sensing voltage V_s increases, the memory cell 22 may be turned on and off more rapidly, allowing the conversion circuit 20 to transmit a greater amount of electric energy to the storage circuit 30. In other words, as the level of the sensing voltage V_s increases, the conversion circuit 20 may transmit, to the storage circuit 30, the input voltage V_in in the form of a cycle signal with a higher frequency and greater amplitude.

As a result, as illustrated in FIGS. 3A and 3B, the conversion circuit 20 may generate the input voltage V_in with a higher frequency and greater amplitude as the level of the sensing voltage V_s increases.

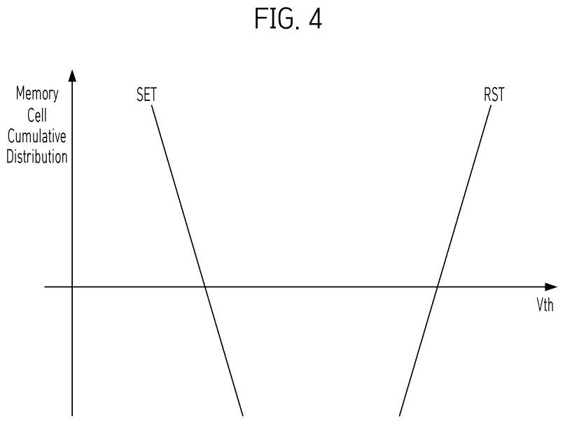

FIGS. 4, 5, 6A, and 6B describe characteristics of memory that is used in the artificial nociceptor according to an embodiment of the present disclosure.

Referring to FIG. 4, the memory cell included in the artificial nociceptor may switch between a set state SET and a reset state RST based on the direction of a current flowing through it. In this case, the threshold voltage of the memory cell in the set state SET may have a lower level than the threshold voltage of the memory cell in the reset state RST. Furthermore, when a current flows in a first direction through the memory cell, the memory cell may switch to the set state SET. Conversely, when a current flows in a second direction through the memory cell, the memory cell may switch to the reset state RST. In this case, the voltage difference between the two ends of the memory cell may exceed the threshold voltage in the reset state RST.

To check whether the memory cell is in the set state SET or the reset state RST, a current in the first direction may be provided to the memory cell. In this case, the voltage difference between both ends of the memory cell may fall between the threshold voltage levels of the set state SET and the reset state RST.

In an embodiment, if a bit line is connected to one end of a memory cell and a word line is connected to the other end of the memory cell, the memory cell may switch to the set state SET or the reset state RST based on the direction of a current when the voltage difference between the bit line and the word line is greater than the threshold voltage of the memory cell in the reset state RST. In this case, when the current flows from the bit line to the word line through the memory cell, the current flow direction is defined as the first direction. When the current flows from the word line to the bit line through the memory cell, the current flow direction is defined as the second direction.

Furthermore, in order to check whether the memory cell is in the set state SET or the reset state RST, the artificial nociceptor may be configured to create a voltage difference between the bit line and the word line that falls between the threshold voltages of the set state SET and the reset state RST and to apply a current in the first direction to the memory cell. In this case, the memory cell may be turned on if the memory cell is in the set state SET, and may remain off if the memory cell is in the reset state RST. A larger current may flow through the memory cell that is turned on than through one that is turned off. Accordingly, it is possible to check whether the memory cell is in the set state SET or the reset state RST by detecting the amount of the current that flows through the memory cell.

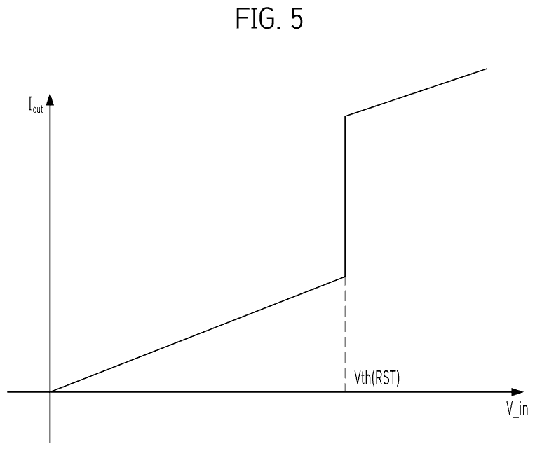

FIG. 5 is a graph illustrating the relationship between the input voltage V_in provided to the memory cell in the reset state RST and the amount of a current Iₒᵤₜ flowing through the memory cell. In this case, the input voltage V_in may be provided by the conversion circuit 20 shown in FIG. 1. Furthermore, the input voltage V_in may correspond to a voltage difference between both ends of the memory cell.

The artificial nociceptor may be configured such that the current Iout flows in the first direction by providing the input voltage V_in to both ends of the memory cell in the reset state RST.

Referring to FIG. 5, as the input voltage V_in gradually increases, the current Iₒᵤₜ flowing through the memory cell increases slowly. When the input voltage V_in exceeds the threshold voltage Vₜₕ (RST) of the memory cell in the reset state RST, the memory cell may be turned on. Once the memory cell is turned on, the current Iₒᵤₜ flowing through the memory cell may increase sharply.

As a result, the memory cell may switch to the set state SET when the memory cell in the reset state RST is turned on, allowing a current to flow through the memory cell in the first direction.

After all of the memory cells included in the storage circuit 30 of the artificial nociceptor switch to the reset state RST, the input voltage V_in provided through the sensor 10 and the conversion circuit 20 may be applied to the memory cells included in the selected area of the storage circuit 30. Accordingly, the memory cells included in the selected area of the artificial nociceptor may each switch to the set state SET when the intensity (or threshold) of a damaging force detected by the sensor 10 exceeds a predetermined threshold. At this time, the level of the input voltage V_in generated by the conversion circuit 20, based on the detected damaging force, may be higher than the level of the threshold voltage Vₜₕ (RST) of the memory cell in the reset state RST.

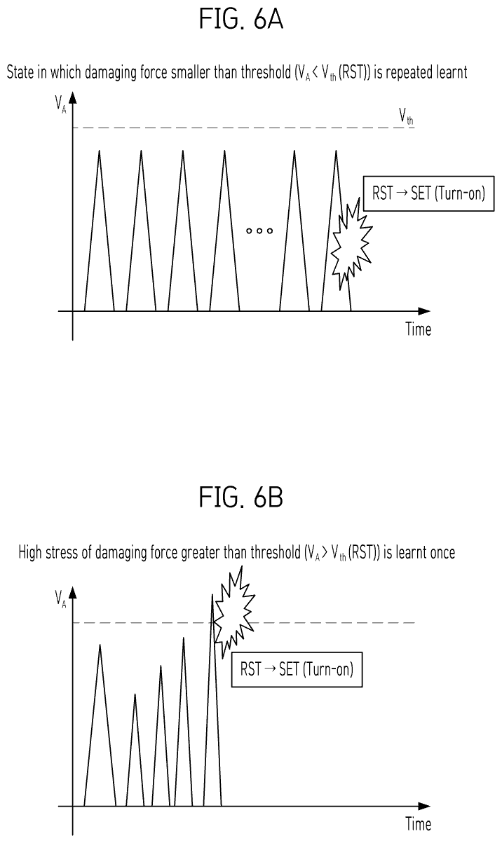

FIG. 6 is a graph illustrating the relationship between the input voltage V_in provided to the memory cell in the reset state RST and the state of the memory cell (whether it is turned on or off). In this case, the input voltage V_in may be provided by the conversion circuit 20 shown in FIG. 1. Furthermore, the input voltage V_in may represent the voltage difference between both ends of the memory cell.

The artificial nociceptor may be configured such that the current Iₒᵤₜ flows in the first direction by providing the input voltage V_in to both ends of the memory cell in the reset state RST.

Referring to FIG. 6A, if the input voltage V_in that is lower than the threshold voltage Vₜₕ (RST) of the memory cell in the reset state RST is continuously and repeatedly provided to the memory cell, it may cause the memory cell to be turned on and switch to the set state SET. Such a phenomenon is known as a read disturbance phenomenon in which the memory cell in the reset state RST unintentionally switches to the set state SET during repeated read operations.

After all of the memory cells included in the storage circuit 30 of the artificial nociceptor switch to the reset state SET, the input voltage V_in provided through the sensor 10 and the conversion circuit 20 may be applied to the memory cells that are included in the selected area of the storage circuit 30.

Accordingly, the memory cells included in the selected area of the artificial nociceptor may switch to the set state SET when a damaging force with an intensity (or threshold) lower than a predetermined threshold is repeatedly detected by the sensor 10. In this case, a voltage level V_{A} of the input voltage V_in generated by the conversion circuit 20, based on the damaging force detected by the sensor 10, may be lower than that of the threshold voltage Vth (RST) of the memory cell in the reset state RST.

Referring to FIG. 6B, when the voltage level V_{A} of the input voltage V_in exceeding that of the threshold voltage Vₜₕ (RST) of the memory cell in the reset state RST is provided to the memory cell in the reset state RST, it may cause the memory cell to be turned on and switch to the set state SET. Such an operation may correspond to a write operation that changes the state of the memory cell from the reset state RST to the set state SET.

After all of the memory cells included in the storage circuit 30 of the artificial nociceptor switch to the reset state RST, the input voltage V_in provided through the sensor 10 and the conversion circuit 20 may be applied to the memory cells included in the selected area of the storage circuit 30.

Accordingly, the memory cells included in the selected area of the artificial nociceptor may switch to the set state SET when the sensor 10 detects a damaging force with an intensity (or threshold) greater than a predetermined threshold. In this case, the level of the input voltage V_in generated by the conversion circuit 20, based on the detected damaging force, may exceed that of the threshold voltage Vₜₕ of the memory cell in the reset state RST.

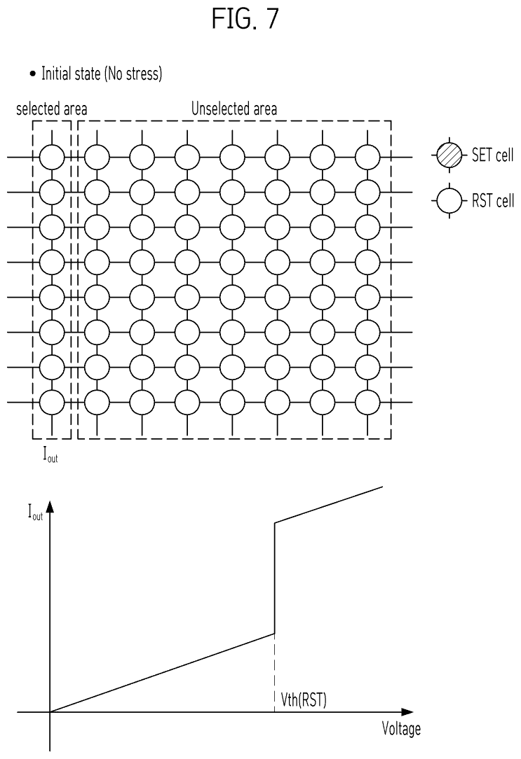

FIGS. 7 to 9 describe an operation of the artificial nociceptor according to an embodiment of the present disclosure.

FIG. 7 illustrates the state in which all of the memory cells in the storage circuit 30 of FIG. 1 have switched to the reset state RST. In this case, the storage circuit 30 may be divided into a selected area and an unselected area. The memory cells included in the selected area may receive the input voltage V_in generated by the conversion circuit 20, which is based on a damaging force detected by the sensor 10. In FIG. 7, the output current Iₒᵤₜ represents the amount of a current flowing through the memory cells included in the selected area, and a voltage Voltage represents the level of the input voltage V_in.

Referring to FIG. 7, all of the memory cells included in the storage circuit 30 may be in the reset state RST. The case in which all of the memory cells included in the storage circuit 30 are in the reset state RST, as illustrated in FIG. 7, may be defined as an initial state I. The initial state I may be defined as a case in which any memory cell that has switched to the set state SET due to a damaging force detected by the sensor 10 is not present in the selected area.

Accordingly, the artificial nociceptor may switch the state of the memory cells included in the storage circuit 30 to the reset state RST in an initial operation.

Therefore, FIG. 7 illustrates the initial state I in the initial operation. Furthermore, FIG. 7 illustrates a case in which a memory cell that has switched to the set state SET by a damaging force detected by the sensor 10 is not present in the selected area of the artificial nociceptor. In other words, FIG. 7 shows the state in which stress has not been applied to the artificial nociceptor (No stress).

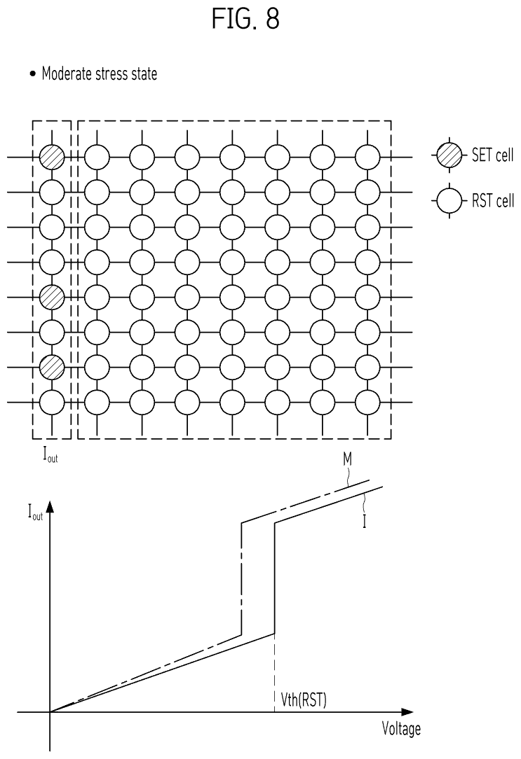

FIG. 8 illustrates that some of the memory cells included in the selected area of the storage circuit 30 in FIG. 1 has switched from the reset state RST to the set state SET. In this case, the memory cells included in the selected area may receive the input voltage V_in that is generated by the conversion circuit 20 based on a damaging force detected by the sensor 10. In FIG. 8, the output current Iₒᵤₜ represents the amount of a current flowing through the memory cells included in the selected area and a voltage Voltage represents the level of the input voltage V_in.

The memory cells included in the storage circuit 30 may exhibit different characteristics due to process, voltage, and temperature (PVT) variations. As a result, even though the input voltage V_in is applied to all the memory cells simultaneously, the timing at which each memory cell switches its state may vary.

As illustrated in FIG. 8, when only some of the memory cells included in the selected area of the storage circuit 30 have switched to the set state SET, it may indicate that the sensor 10 is repeatedly applying a damaging force below a threshold to the memory cells of the selected area. In this case, the amount of the current Iₒᵤₜ flowing through the memory cells in the selected area may be greater than the amount of a current in the initial state I.

The case in which only some of the memory cells included in the selected area have switched to the set state SET, as illustrated in FIG. 8, may be defined as a moderate stress state M. The amount of the current Iₒᵤₜ in the moderate stress state M may be greater than the amount of the current Iₒᵤₜ in the initial state I.

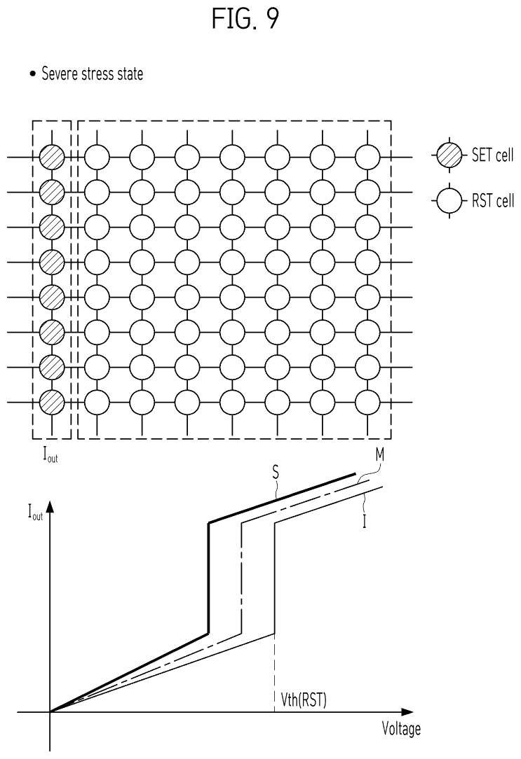

FIG. 9 illustrates that all of the memory cells included in the selected area of the storage circuit 30 in FIG. 1 have switched from the reset state RST to the set state SET. In this case, the memory cells included in the selected area may receive the input voltage V_in that is generated by the conversion circuit 20 based on a damaging force detected by the sensor 10. In FIG. 9, the output current Iₒᵤₜ represents the amount of a current flowing through the memory cells included in the selected area, and a voltage Voltage represents the level of the input voltage V_in.

When the input voltage V_in higher than the highest threshold voltage is provided to memory cells in the reset state RST within the selected area of the storage circuit 30, all of the memory cells in the selected area may switch to the set state SET. Alternatively, the input voltage V_in lower than the threshold may be repeatedly provided to all of the memory cells included in the selected area of the storage circuit 30 until they have all switched to the set state SET.

Accordingly, the case in which all of the memory cells included in the selected area of the storage circuit 30 have switched to the set state SET, as illustrated in FIG. 9, may occur when the sensor 10 provides a damaging force greater than the threshold to the memory cells, or when the sensor 10 repeatedly provides a damaging force smaller than the threshold to the memory cells. In this case, the amount of the current Iₒᵤₜ flowing through the memory cells in the selected area may be greater than the amount of the current observed in the moderate stress state M.

The case in which all of the memory cells included in the selected area have switched to the set state SET, as illustrated in FIG. 9, may be defined as a severe stress state S. The amount of the current Iₒᵤₜ in the severe stress state S may be greater than the amount of the current Iₒᵤₜ in the moderate stress state M.

As described above, the artificial nociceptor according to the embodiment of the present disclosure may include the sensor that converts an external damaging force into electric energy. The conversion circuit generates the input voltage in the form of a cycle signal with amplitude and a frequency changed based on the electric energy provided by the sensor. Memory cells in the storage circuit selectively switch from the reset state to the set state based on the input voltage.

Accordingly, the artificial nociceptor according to the embodiment of the present disclosure can distinguish between the absence of stress, the moderate stress state, and the severe stress state by switching the state of the memory cells included in the storage circuit based on a damaging force detected by the sensor.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. An artificial nociceptor, comprising:
a sensor configured to convert a damaging force into electric energy;
a conversion circuit configured to generate an input voltage in the form of a cycle signal, wherein a frequency and amplitude of the cycle signal change based on the electric energy; and
a storage circuit comprising a plurality of memory cells and configured to receive the input voltage and supply the input voltage to first memory cells in a selected area among the plurality of memory cells.

2. The artificial nociceptor of claim 1, wherein the damaging force comprises one or more of pressure, force, and acceleration.

3. The artificial nociceptor of claim 1, wherein the first memory cell comprises a chalcogenide-series ovonic threshold switch (OTS) material.

4. The artificial nociceptor of claim 1, wherein a level of a threshold voltage of the first memory cell changes based on a direction of a current that flows through the first memory cell.

5. The artificial nociceptor of claim 1, wherein the conversion circuit comprises:
a voltage circuit configured to generate a first voltage based on the electric energy,
a second memory cell configured to provide a second voltage by being repeatedly turned on and off based on a level of the first voltage, and
a transistor configured to receive the second voltage and supply it to the storage circuit as the input voltage.

6. The artificial nociceptor of claim 5, wherein the voltage circuit changes the level of the first voltage based on the electric energy.

7. The artificial nociceptor of claim 6, wherein the second memory cell has one end receiving the first voltage and has the other end connected to the transistor.

8. The artificial nociceptor of claim 7, wherein a cycle in which the second memory cell is turned on and off shortens as a voltage level at the one end increases.

9. The artificial nociceptor of claim 8, wherein the second memory cell is turned on when the voltage level at the one end exceeds a level of a threshold voltage and is turned off when the voltage level at the one end drops below the level of the threshold voltage.

10. The artificial nociceptor of claim 9, wherein the second memory cell has characteristics identical to those of the first memory cell.

11. The artificial nociceptor of claim 9, wherein:
the transistor has a gate receiving the first voltage and a drain connected to the other end of the second memory cell, and
the input voltage is output from a source of the transistor.

12. The artificial nociceptor of claim 10, wherein:
a degree to which the transistor is turned on is changed based on the level of the first voltage, and
the transistor outputs the input voltage with greater amplitude as the degree becomes greater.

13. The artificial nociceptor of claim 1, wherein the input voltage corresponds to a difference between voltage levels at both ends of each of the first memory cells included in the selected area.

14. The artificial nociceptor of claim 13, wherein the selected area stores an intensity of stress based on a number of first memory cells that switch from a reset state to a set state in response to the input voltage.

15. The artificial nociceptor of claim 14, wherein the intensity of stress comprises an initial state, a moderate stress state, and a severe stress state.

16. The artificial nociceptor of claim 15, wherein in the initial state, all of the first memory cells included in the selected area are in the reset state.

17. The artificial nociceptor of claim 15, wherein in the moderate stress state, some of the first memory cells included in the selected area are in the set state.

18. The artificial nociceptor of claim 15, wherein in the severe stress state, all of the first memory cells included in the selected area are in the set state.

19. An operating method of an artificial nociceptor, the method comprising:
switching a state of memory cells in a storage circuit to a reset state;
detecting a damaging force using a sensor;
generating an input voltage corresponding to the damaging force;
providing the input voltage to memory cells in a selected area of the storage circuit; and
determining an intensity of stress of the damaging force based on an amount of current that flows through the memory cells in the selected area.

20. The operating method of claim 19, wherein the generating of the input voltage comprises generating the input voltage with a frequency and amplitude that vary based on an intensity of the damaging force.

21. The operating method of claim 20, wherein the generating of the input voltage comprises generating the input voltage with a higher frequency and greater amplitude as the intensity of the damaging force increases.

22. The operating method of claim 19, wherein in the determining of the intensity of stress, the amount of current changes based on a number of memory cells that switch to the set state among the memory cells receiving the input voltage.

23. The operating method of claim 22, wherein the determining of the intensity of stress comprises determining that the intensity of stress is greater as the amount of the current increases.
